(19) United States
(12) Patent Application Publication
(10) Pub. No.: US 2011/0215797 A1
(43) Pub. Date: Sep. 8, 2011

(54) MAGNET ASSEMBLY

(75) Inventors: Klaus Manfred Steinich, Zorneding / Poring (DE); Georg Cuntze, Markt Schwaben (DE)

(73) Assignee: ASM Automation Sensorik Messteehnik GmbH

(21) Appl. No.: 13/040,647

(22) Filed: Mar. 4, 2011

(30) Foreign Application Priority Data
Mar. 5, 2010 (DE) 102010010388.8

(51) Int. Cl. G01B 7/30; G01R 33/02

(52) U.S. Cl. 324/207.25; 324/244

(57) ABSTRACT

In order to amplify a use field of a position giving magnet of a magnetic field sensitive sensor and in order to reduce the scatter field, a magnetic interconnection made from plural magnets preferably arranged in longitudinal direction behind one another is being used, wherein the pole orientations of the magnets differ from one another and are arranged in particular symmetrical to the center element.

### I. FIELD OF THE INVENTION

The invention relates to a magnet interconnection, in particular an encoder magnet for a magnetic field sensitive sensor, a position sensor, or an angle sensor.

### II. BACKGROUND OF THE INVENTION

Magnetic field sensitive sensors react to a magnet field of an encoder magnet that is arranged movable relative to an actual sensor, wherein the encoder magnet is typically configured as a permanent magnet or includes a permanent magnet. In exceptional embodiments it can also be an electromagnet.

Thus, only a portion of the magnetic field generated by the encoder magnet, namely only the magnetic use field emitted in use direction towards the sensor element is being utilized, whereas the magnetic field of the encoder magnet emitted in all other directions, thus the scatter directions, is not required but to the contrary, depending on its orientation and range, it can also affect the measuring result negatively.

Thus, it is insignificant as a matter of principle, whether the measurement value is in a rotation position, this means the sensor measures an angle, or the measurement value is a lateral position, this means the sensor measures a distance.

For an angle sensor, e.g. the direction of the magnetic field of the encoder magnet is determined touch free through one or plural Hall sensor or also through XMR sensors.

In linear sensors a position or movement of an encoder magnet relative to a reference position is determined touch free. Thus, the magnetic field can be determined directly through one or plural Hall sensors or XMR sensors, or indirectly e.g. through the saturation of magnetic cores (permanent-magnetic linear contactless displacement sensor—PLCD)

It is also feasible that the permanent magnet generates a pulse through its magnetic field, wherein the pulse is subsequently detected through an additional sensor element like it is the case e.g. for magnetostrictive position sensors.

In a position sensor of this type an encoder magnet, which can be mounted e.g. at a movable machine element, causes a magneto-elastic density wave, (MEDW) which propagates in a wave conductor arranged in the sensor. A time difference between the creation of the MEDW and its detection at one end of the wave conductor is used as a measurement value for determining a position.

The exact function of a position sensor of this type is sufficiently known, thus a detailed description can be omitted.

It is particular for all sensors actuated by permanent magnets and of particular interest for the present invention that the sensor characteristics are substantially determined by the type of the magnetic field of the encoder magnet (position magnet), this means not only through the maximum field strength and primary orientation, but also through its local shape and propagation.

Thus a position magnet with high field strength can have e.g. a greater distance between the position magnet and the sensor, than for a magnet with low field strength.

On the other hand side, a magnet whose field strength very limited in particular locations, can lead to a better position resolution for the sensor.

For example when an application requires plural position magnets at a sensor, a position magnet with a field strength that is very much reduced at particular locations is advantageous, since this indirectly determines the minimum distance between two adjacent position magnets.

For some types of sensors, in particular the direction of magnetization of the encoder magnet is relevant for the sensor principle, e.g. for angle sensors.

For other types of sensors, the dependency from the magnetization directions can rather be detrimental, since this can lead to sensor malfunctions when a user mixes them up. In situations like that, a symmetric design of the encoder magnet is preferred.

According to a particular configuration of the position sensor magnets can be used, whose magnetic orientations are aligned parallel to the sensor (so called axial orientation), or which are e.g. also aligned perpendicular to the axis of the sensor (radial orientation). Magnetic sensors are also provided in rod form, wherein the position magnet can have a locally variable orientation, and wherein the orientation is aligned radially to the sensor (so called radial orientation.

In order to improve the characteristics of position magnets for magnetic position sensors numerous proposals were made.

Von Stoll et al. propose e.g. in U.S. Pat. No. 5,514,961 to use an axially oriented ring magnet for a rod shaped sensor, wherein a steel ring is attached at the face of the magnet.

The steel ring is made from simple magnetizable steel which conducts the flux lines at one end of the magnetic ring as a flux conductor.

The flux lines at this location impact the sensor rod in a concentrated manner at a steeper angle and lead to a stronger and more defined magnetic pulse which provides a better function for the sensor.

The disadvantage of an axial magnet, however, is that the propagation of the magnetic field is not independent from the installed position of the magnet and thus the properties of the sensor depend on how the position magnet is oriented. Thus, the position magnet is not universally usable.

Another disadvantage is that the field strength of an axial magnet based on its orientation has a high percentage of flux lines parallel to the sensor rod which leads to a strong remote effect when the magnet is oriented incorrectly.

A remote effect of this type of the position magnet can e.g. degrade the sensor properties when the position magnet is proximal to the detector at an end of a magetostrictive wave conductor.

Another proposal is disclosed by von Sprecher et al. in U.S. Pat. No. 6,271,660 which discloses a particular arrangement to increase the use signal of the magnet.

This document uses a position magnet whose magnetic orientation is directed towards the position sensor (perpendicular/radial orientation) and combine the magnet with two additional magnets which are arranged in the same direction (also radial) parallel to the first magnet but which have opposite orientation so that the north pole of one magnet is placed adjacent to the south pole of the other magnet (anti-polar arrangement).

This arrangement facilitates to superimpose the sensor signals of the particular magnets in a magnetostrictive sensor so that the extremes of the signal are reinforced and thus the rate of change of the sensor signal is increased. However, no controlled superposition of opposite magnetic fields is provided.

This facilitates a greater distance between a magnet and a sensor. However, an arrangement of this type causes a greater width of the magnet since the width of the magnets should be substantially identical for an optimum superposition of the particular pulses.

The distance of the particular magnets is determined by the run-time of the MEDW in the wave conductor.

Additionally a non-magnetic gap has to be provided between the particular magnets since otherwise the anti-polar magnets would magnetically short one another which would cause a reduction of the available field strength.

Additionally the effect of unilateral field strength amplification was used first by J. C. Mallinson (J. C. Mallinson, One-Sided Fluxes A Magnetic Curiosity, JEEE Transactions on Magnets, 9,678-682, 1973).

A combination of magnets with a magnetization that is respectively offset by 90° is also known in the art as Halbach-Array and was used for guiding particle beams (K Halbach, Nuclear Instruments and Methods, 169, 1, 1980).

Subsequently Halbach arrays were used in particular for generating strong magnetic fields. Also using cylindrical shapes or spherical shapes is known in the art in order to generate substantially increased field strengths in the center of the cylinder or the sphere.

### III. DETAILED DESCRIPTION OF THE INVENTION

### a) Technical Object

Thus it is the object of the present invention to provide a cost-effective and compact magnet interconnection, in particular for an encoder magnet for a magnetic field sensitive sensor which provides the following:
Improve the field strength in the direction of use
Increase the rate of change of the measurement signal
Reduce the scatter field of the magnet; and
Keep the dimensions of the magnetic interconnection as small as possible in axial direction.

### b) Solution

This object is achieved through the features of claims 1 and 10. Advantageous embodiments can be derived from the dependent claims.

The mutually interfering interconnection magnets with their deviating pole orientations which, however, do not add up to form a simple magnetic loop cause mutual interference of the magnetic field lines of the particular interconnection magnets in a manner so that the field strength of the magnetic interconnection in the desired direction of use is increased. As a consequence thereof, or even as one of the desired main effects also the scatter field in the scatter directions that are not being used shall be reduced.

This object can be achieved on the one hand side through a different actual arrangement of the pole orientations within the interconnection element as a function of the type of magnetic field sensitive sensor that shall be operated with the interconnection element, e.g. a position sensor that extends in one direction in which the useable magnetic field shall be oriented exactly transversely if possible or radially with respect to the longitudinal orientation of the sensor element, or an angle sensor in which the resulting magnetic field shall rotate the typically flat angle sensor in its plane, thus e.g. parallel to the tangential direction of the rotation axis of the angle sensor.

The actual configuration furthermore depends on whether the magnetic interconnection exclusively includes interconnection magnets or also interconnection elements which are no magnets themselves, wherein in turn a differentiation has to be made between magnetizable and known magnetizable elements of the interconnection. The magnetizable elements of the interconnection, e.g. soft iron focus the magnetic flux which is provided at this location anyhow and prevent further scattering of the magnetic flux, but do not change its orientation since the elements of the interconnection are only magnetized by the magnetic flux which is provided at this location anyhow.

Non-magnetizable elements of the interconnection, however, are being used merely as spacers between the interconnection magnets and form the magnetic field of the magnetic interconnection primarily with respect to its spatial dimension through the defined gap, however, they do not qualitatively change the field, thus e.g. with respect to its flow directions at respective locations.

The desired mutual interference of the configuration of the magnetic fields of the interconnection magnets thus is typically the greatest when e.g. for a symmetric arrangement of the interconnection elements at least the center elements, e.g. three elements are interconnection magnets, while the elements of the interconnection which join on the outside can be magnetizable or non-magnetizable elements of the interconnection, thus no interconnection magnets.

Mutual influencing of the magnetic fields as recited supra is e.g. facilitated in that, typically in top view of the plane in which the pole orientations of the interconnection magnets are arranged, the pole orientations in longitudinal direction of the magnetic interconnection change from one interconnection magnet to another respectively in the same direction, in particular respectively by 90°.

Overall, and in particular in view of this pattern, the interconnection magnets are preferably arranged in series, preferably in a straight line behind one another, wherein an uneven number of interconnection elements and in particular a symmetric configuration with respect to the center interconnection element has proven advantageous for most applications.

In order for the interconnection elements to permanently remain in their relative positions which is difficult to accomplish for magnets with different pole orientations which do not complement each other to form a magnetic rail due to the repulsive forces, the interconnection magnets can be glued together, e.g. in that they are inserted into a respective retaining device and subsequently completely incased into plastic material or loosely inserted adjacent to one another in a respective housing that encloses them in a form-locking manner which secures them in a particular position relative to one another. Also gluing the elements of the interconnection together is only possible at the mutual contact surfaces of the elements of the interconnection through a respective device. Theoretically also form locked connections of the elements of the interconnection relative to one another can be selected which, however, typically greatly increases manufacturing complexity.

A typical arrangement of the elements of the interconnection in which a resulting field line orientation in the center interconnection element is achieved transversely to the longitudinal direction of the element of the interconnection is characterized in that the interconnection magnets that are arranged on both sides of the center interconnection element have a pole orientation that extends in longitudinal direction of the magnetic interconnection but with pole orientations opposite to one another.

Thus, when the center element of the interconnection is not a magnet this causes a strong magnetic field that extends in all transversal directions relative to the longitudinal direction of the magnetic interconnection. However, when the center element of the interconnection is also a magnet whose pole orientation is oriented in a particular direction that is transversal to the longitudinal direction of the magnetic interconnection the magnetic field in this particular pole orientation is amplified and widened, in the opposite directions it is weakened and narrowed.

A configuration of the magnet interconnection of this type is e.g. particularly suitable for an encoder magnet arrangement at a magnetic field sensitive distance sensor, whose sensor element is e.g. a wave conductor in which the magnetic interconnection is moved with its longitudinal direction parallel to the longitudinal extension of the sensor element and moved along the sensor element.

Another typical configuration of the magnetic interconnection with at least three interconnection elements is characterized in that the interconnection magnets which join in outward direction on both sides of the center element of the interconnection are arranged with pole orientations parallel to one another and transversal to the longitudinal direction of the magnetic interconnection, but in turn with pole orientations that are opposite to one another. This creates a resultant magnetic field which has an orientation parallel to the longitudinal orientation of the magnetic interconnection at the level of the center element of the interconnection, however, it has the same strength and circumferential direction and in longitudinal direction at all locations.

Thus, when the center element of the interconnection is additionally also an interconnection magnet whose pole orientation, however, extends in the longitudinal direction of the magnetic compound, the resulting magnetic field at the level of the center element of the interconnection is thus amplified on one side of the circumference and spatially widened in radial direction and on the other side however weakened and spatially contracted.

Additional shaping of the magnetic field can be provided in that the magnetic interconnection includes flux conductor elements made from magnetizable material on all sides that differ from the direction of use, thus in all scatter directions, wherein the flux conductor elements focus the magnetic flux closely to the magnetic interconnection in the scatter directions and reduce the expansion of the magnetic flux in the scatter directions.

A magnetic interconnection with an even number of interconnection elements can also be produced according to these principles, wherein the magnetic interconnection includes e.g. only two interconnection magnets which, however, yields a non-symmetrical magnetic field which e.g. expands in a relatively wide manner in one scatter direction. In case this is not detrimental for the planned application, the complexity of fabrication and thus also the cost for producing the interconnection element can be reduced.

### c) Embodiments

Embodiments of the invention are subsequently described in more detail in an exemplary manner with reference to drawing figures, wherein:

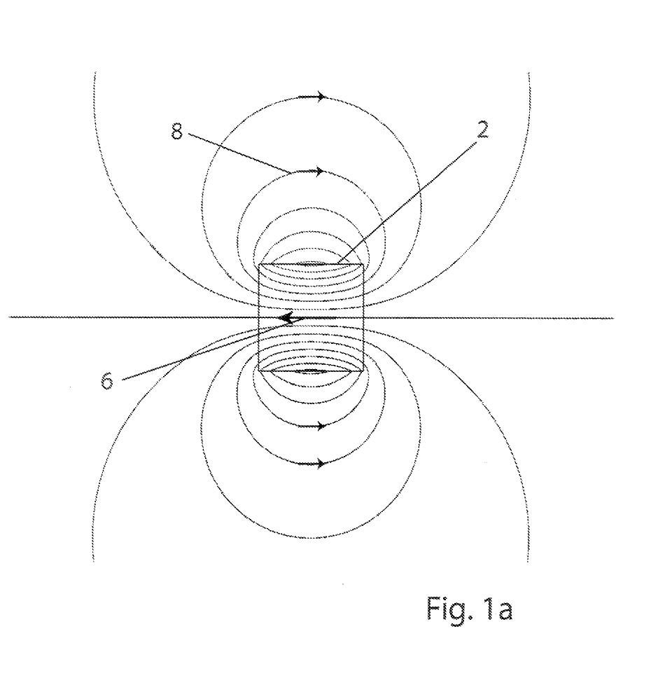

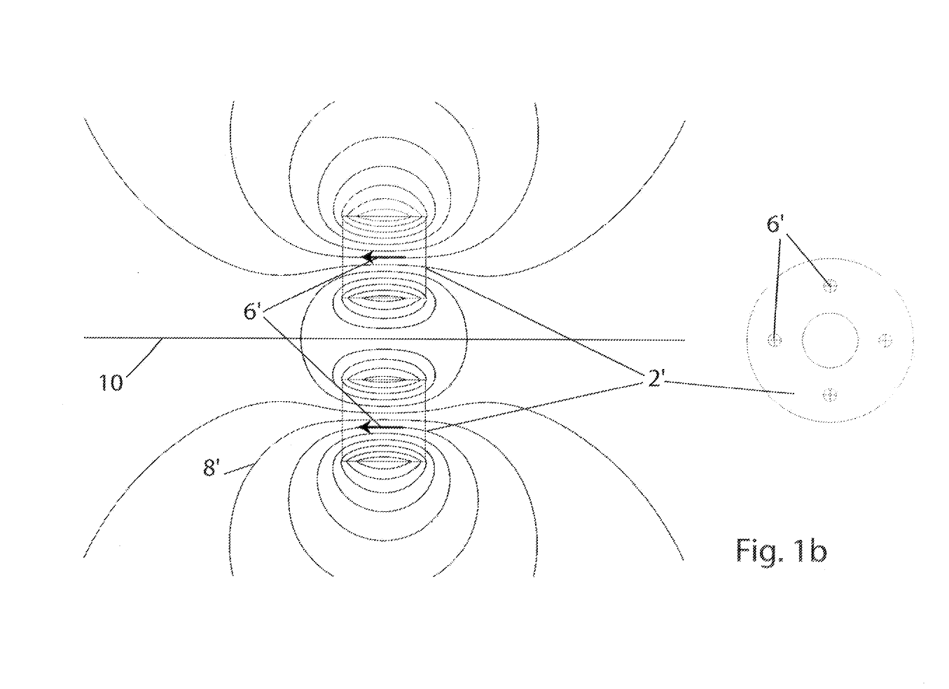

FIG. 1 illustrates a prior art magnet assembly;

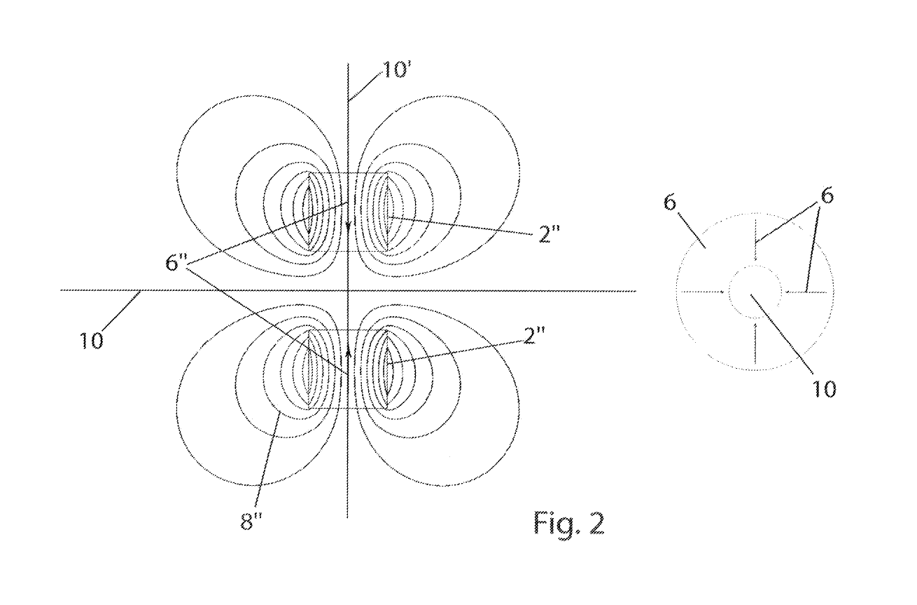

FIG. 2 illustrates a prior art magnet assembly;

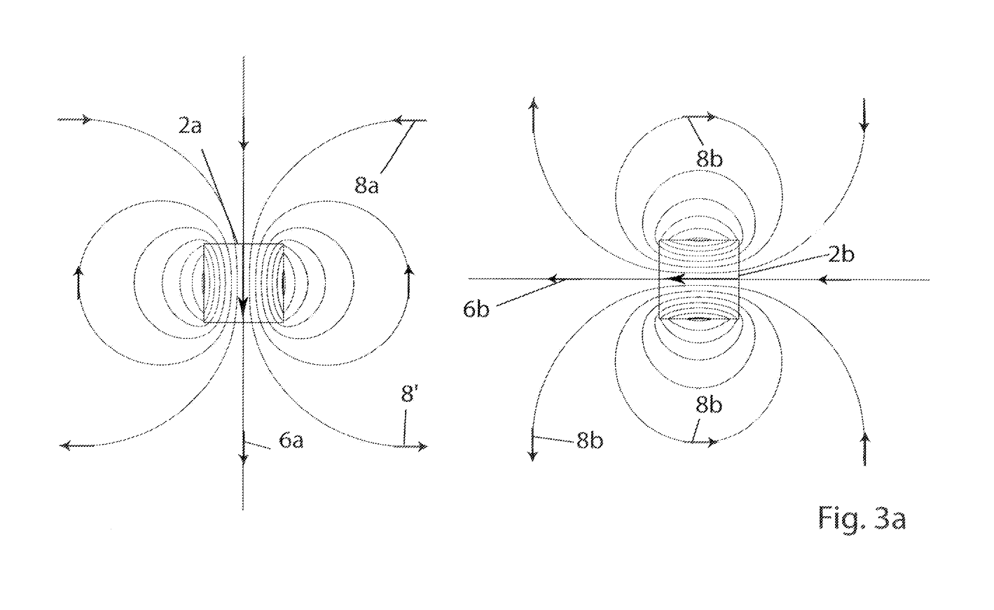

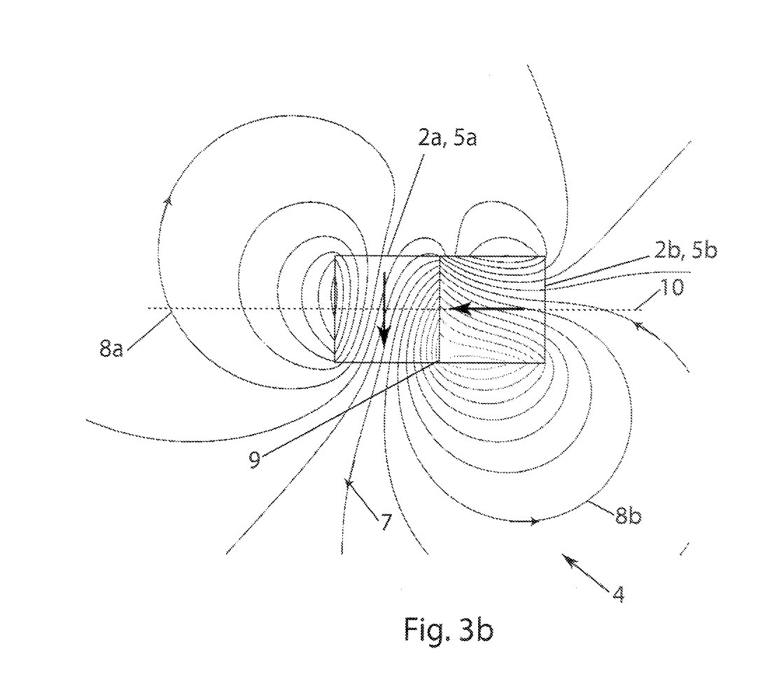

FIG. 3 illustrates the assembly of a first magnet interconnection according to the invention;

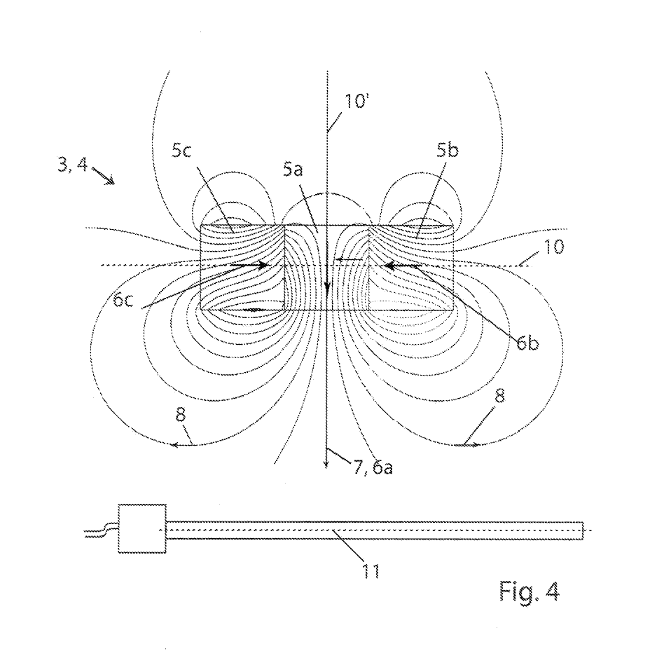

FIG. 4 illustrates a first preferred embodiment;

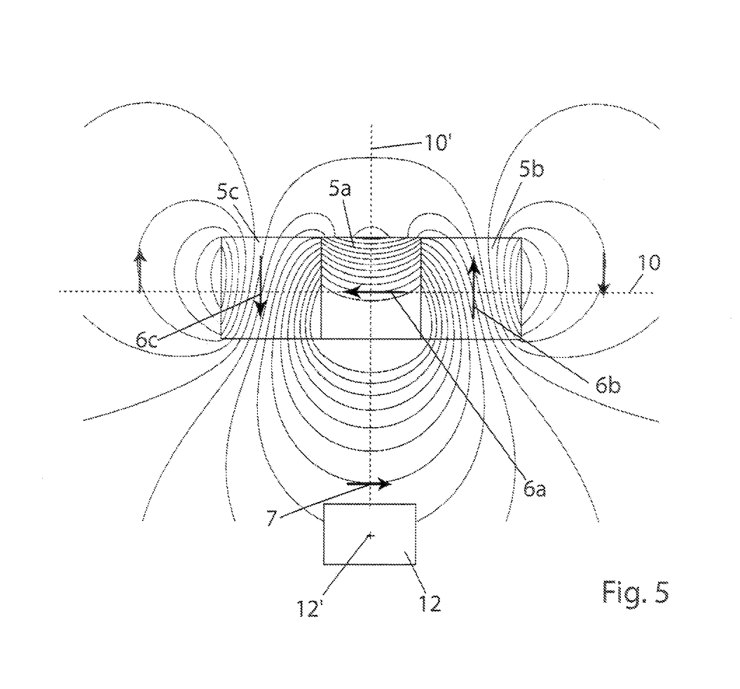

FIG. 5 illustrates a second preferred embodiment;

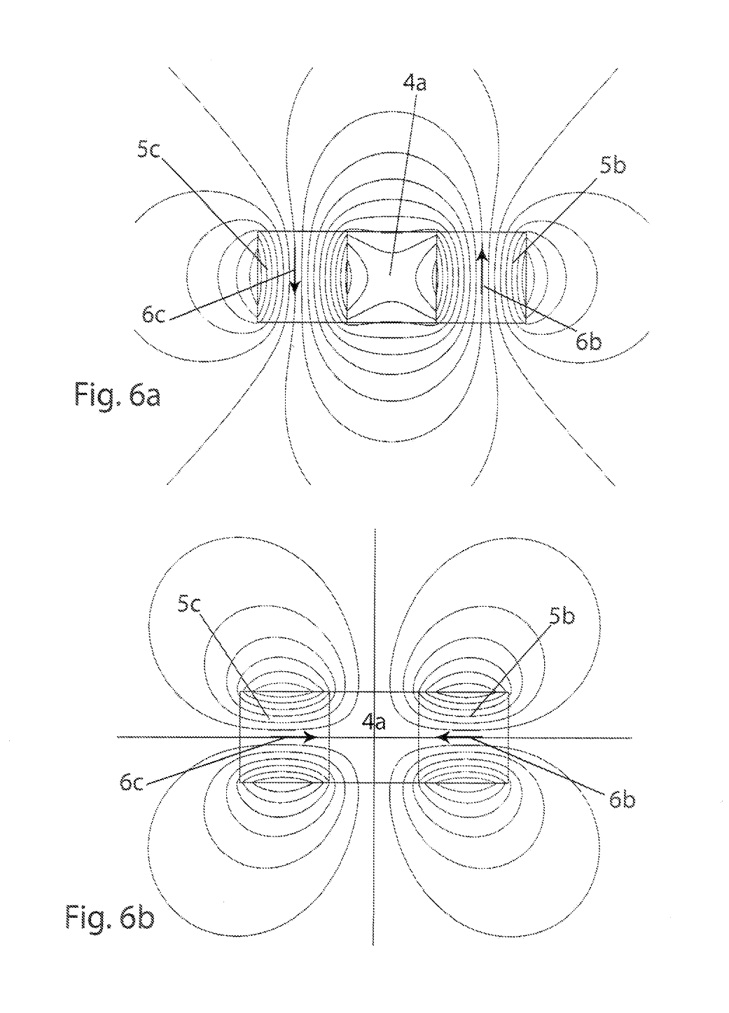

FIG. 6 illustrates a variation of the preferred embodiments;

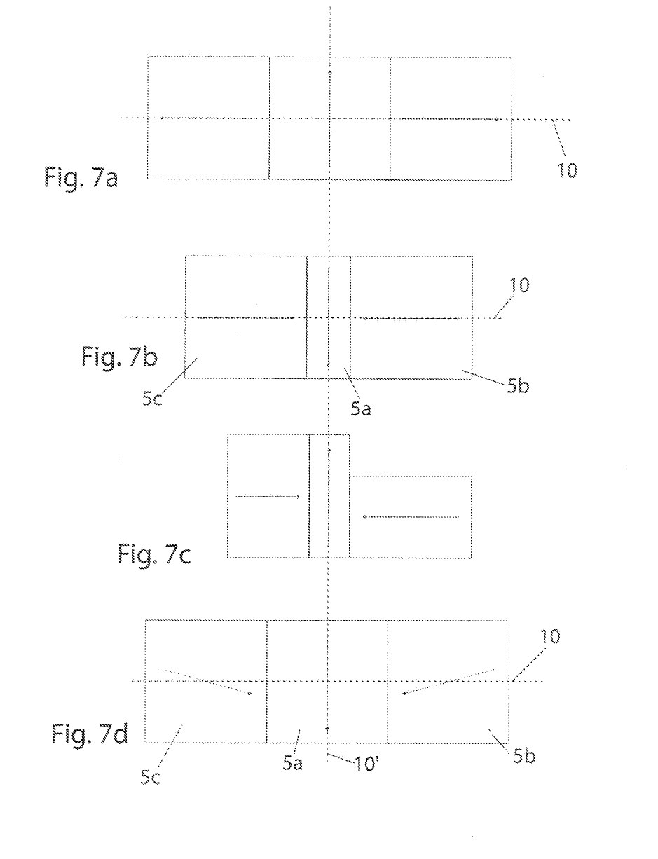

FIG. 7 illustrates schematics of dimensional variations of the preferred embodiments;

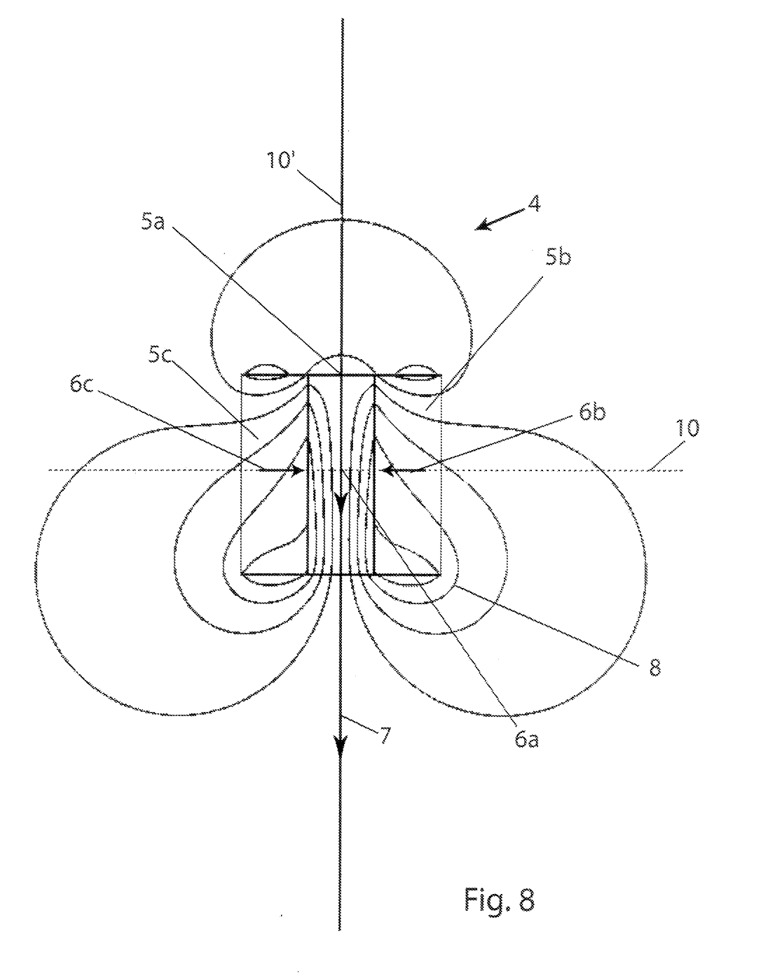

FIG. 8 illustrates a realistic depiction of a dimensional variation of FIG. 7;

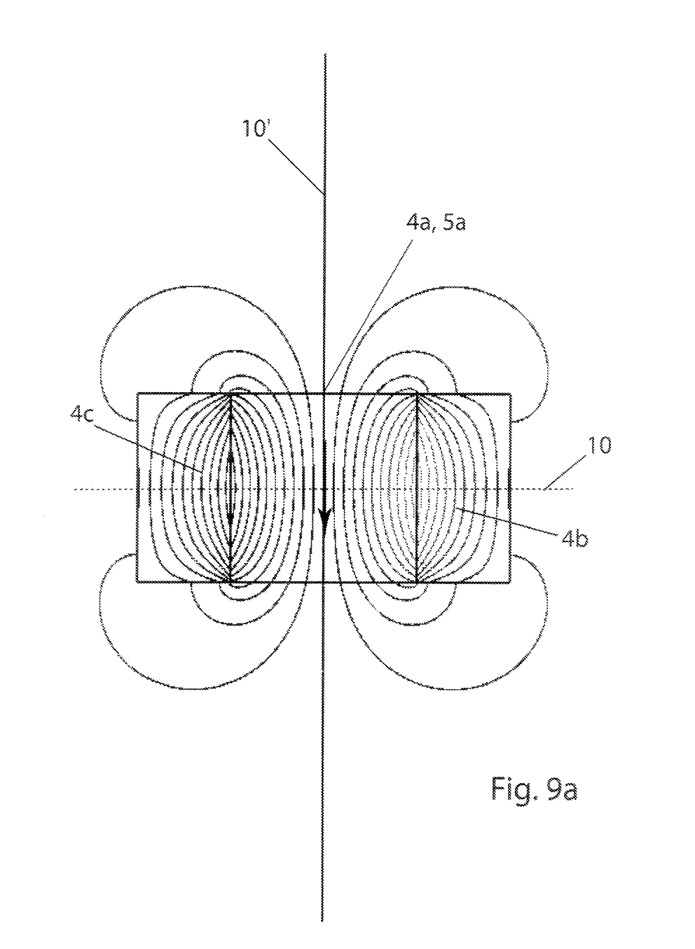

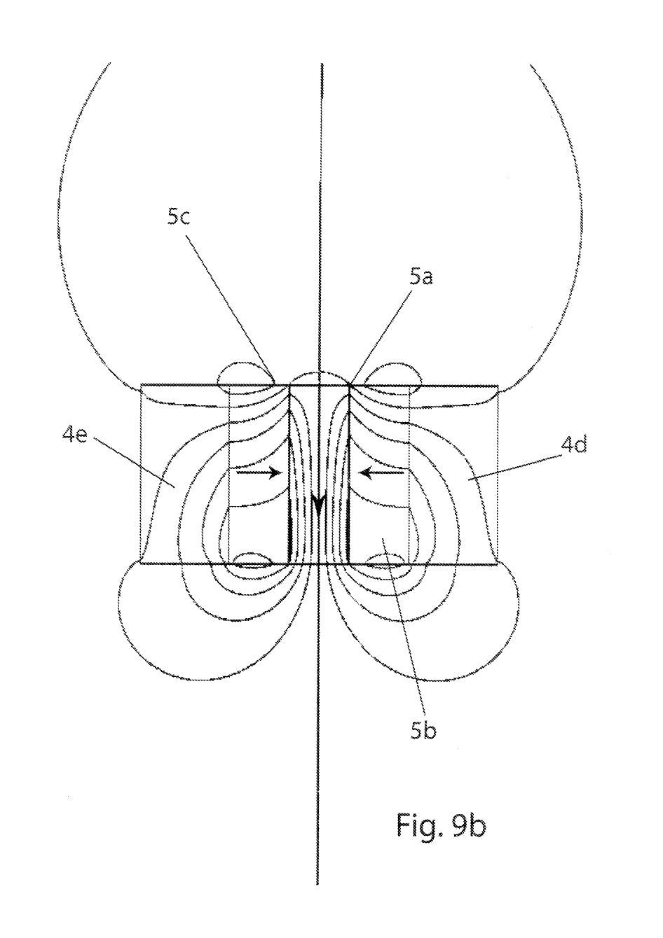

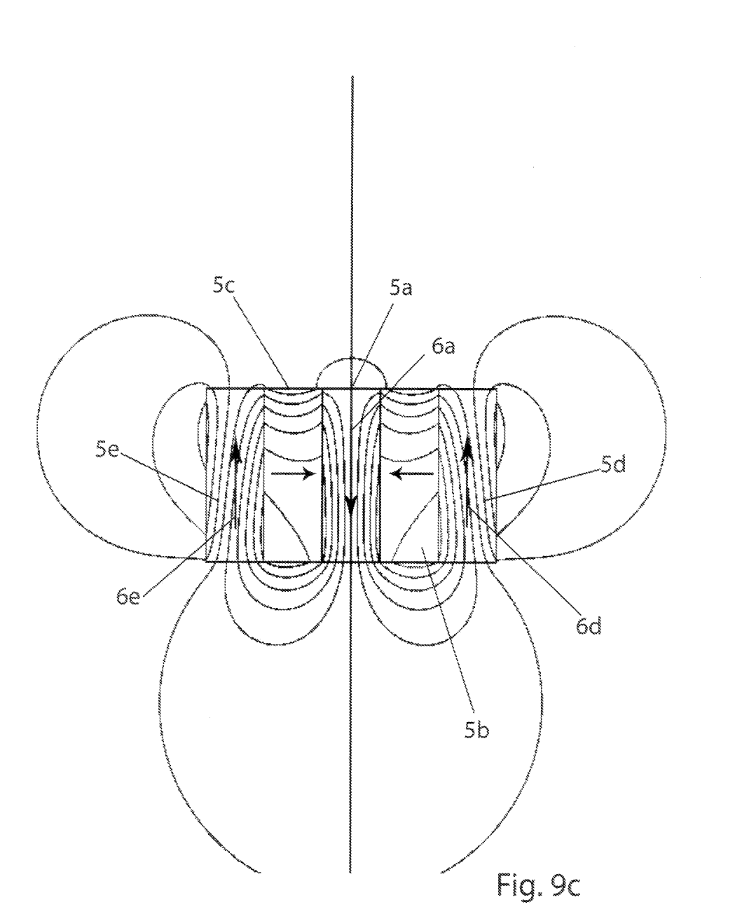

FIG. 9 illustrates another variation of a preferred embodiment;

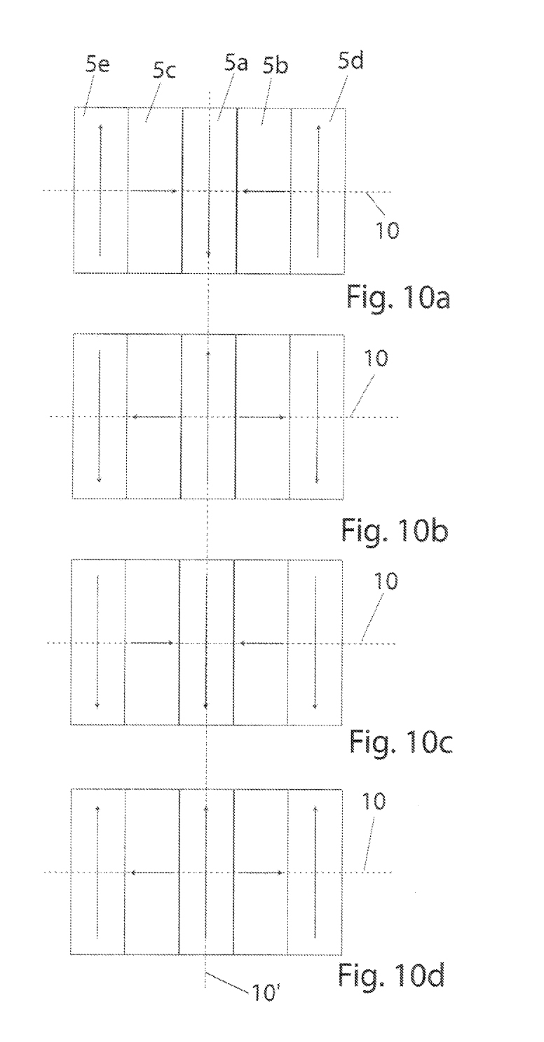

FIG. 10 illustrates schematic depictions of another improvement of the preferred embodiment;

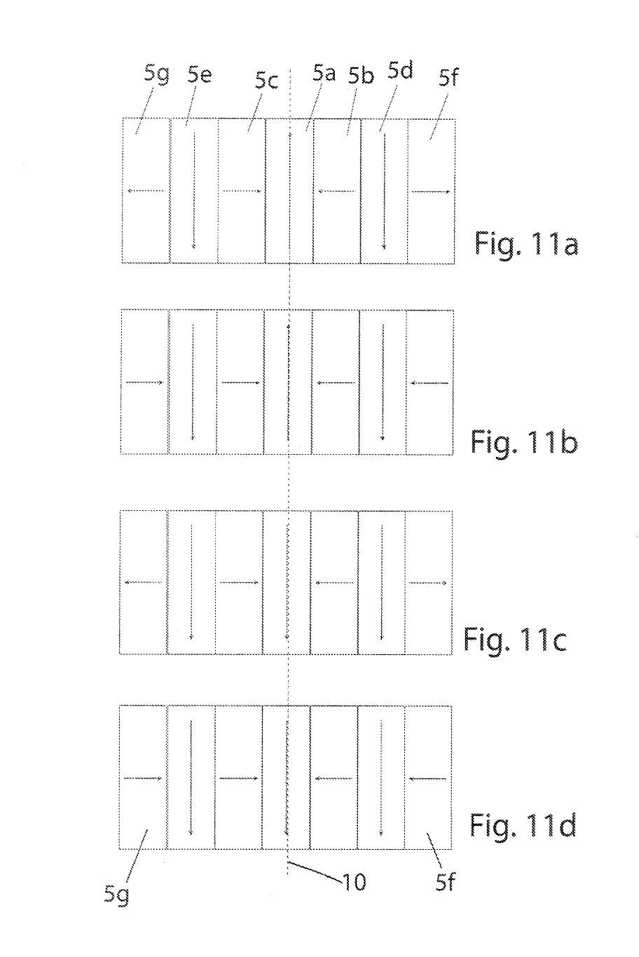

FIG. 11 illustrates schematic depictions of another improvement of the preferred embodiment;

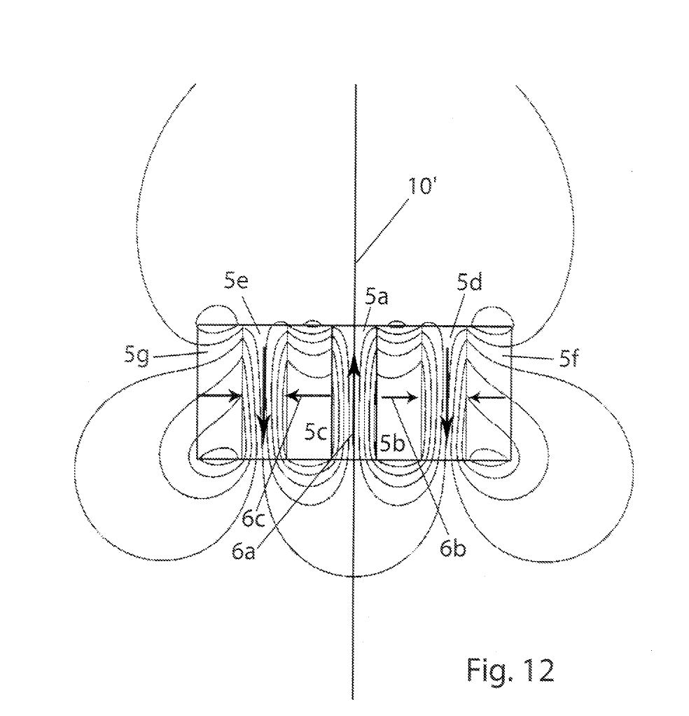

FIG. 12 illustrates a realistic depiction of one of these variants;

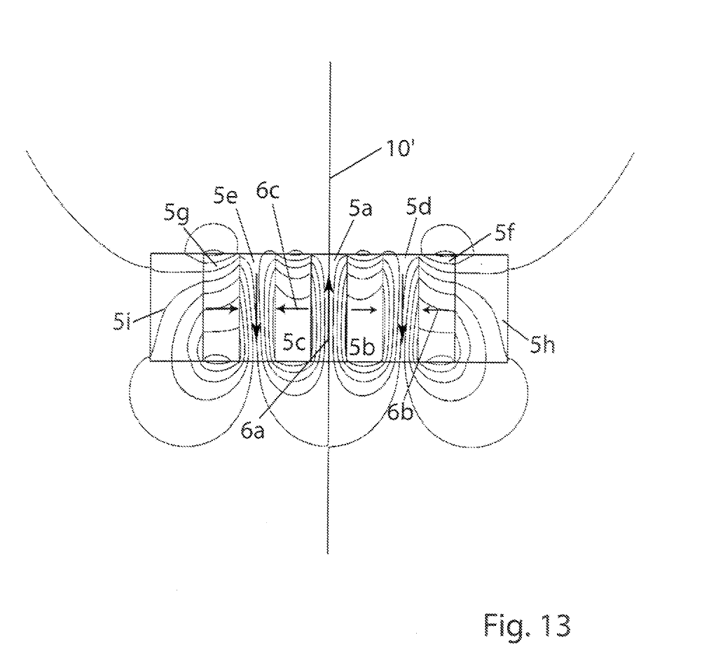

FIG. 13 illustrates a realistic depiction of an improved embodiment

FIGS. 1 and 2 illustrate known magnet arrangements.

FIG. 1a illustrates a particular rod magnet 2 in which the magnetic field lines 6 internally extend from the south pole to the north pole as usual and additionally run back in a curved arc accordingly outside of the magnet from the north pole to the south pole so that respectively closed magnetic field lines are created, wherein the distance of the magnetic field lines from one another in the illustration is the smaller, the greater the magnetic field strength is at the respective location.

For a rod magnet this yields a torus shaped magnetic field about the pole orientation 6 of the magnet 2.

FIG. 1b illustrates a ring magnet 2′ in which the device 6′ extends at all locations parallel to the longitudinal direction 10 of the symmetry axis through the center of the ring magnet 2′.

Thus, significantly higher field strength and thus more closely adjacent field lines 8′ are achieved in the portions remote from the ring magnet 2′ in the interior free space of the ring magnet, then radially outside of the ring magnet. Contrary thereto the pole orientation 6′ extends in the ring shaped magnet 2″ according to FIG. 2 at any location in the ring magnet in radially inward direction towards the longitudinal direction 10 of the magnet 2″, wherein the longitudinal direction 10 forms the symmetry axis of the rotation symmetric ring magnet 2″.

This creates a magnetic field in which the field lines 8″ are formed as a double torus, whose two halves are arranged symmetrical to a transversal plane 10′ orthogonal to the longitudinal direction 10 extending through the center of the ring magnet 2′.

The concentration of the field lines in the interior free space of the annular magnet 2″ thus is very small, while high field strength is provided on the longitudinal axis 10 axially outside of the portion of the magnet 2, 2″.

The known embodiments are being used in order to optionally achieve high or low field strength in the gap within the ring magnet or axially offset there from.

It is evident that all pole orientations are thus arranged in the same direction, either parallel to one another or opposite to one another.

The FIG. 3 seqq., however, illustrate the following embodiments according to the invention.

FIG. 3a in turn illustrates two particular rod magnets 2a, b with their respective torus shaped field lines 8a, 8b and pole orientations 6a, 6b, wherein the rod magnets are illustrated remote from one another so that they do not interfere with other, wherein the pole orientations 6a, 6b intersect at right angles.

When the particular rod magnets 2a, b are moved closer together according to FIG. 3b, so that the magnetic fields influence one another, in the extreme until the two e.g. cube shaped rod magnets 2a, b contact one another so that they can be glued together at their contact surface 9, this yields a non-symmetrical magnetic field as illustrated in FIG. 3b. The torus shape of the magnetic field lines 8a or 8b is only respectively provided half in each of the two particular interconnection magnets 2a, b, broadly speaking approximately only respectively on the side facing away from the approaching other interconnection magnet 2a, b, while a strong change of the magnetic field has occurred in the portion there between.

In the direction of the resulting vector sum from the two particular pole orientations 6a, b of the interconnection magnets 2a, b a strong field strength is created in the summation direction oriented away from the interconnection magnet 4a, b, the use direction 7, on the other hand a very weak magnetic field is created in the direction oriented towards the magnetic interconnection 4.

In the use-direction 7, thus already an amplification of the magnetic field has been achieved, however, the scatter field in all other directions and thus in all directions about the longitudinal direction 10, the direction of the sequence of the particular interconnection elements 1a, b behind one another, is still very large, in particular it has the same size in all directions.

FIG. 4 illustrates how this can be prevented by configuring the magnetic interconnection 4 symmetrically, namely mirror symmetrical to the transversal plane 10′ oriented orthogonal to the longitudinal direction 10 of the magnet interconnection. For this purpose an additional magnet 2c is added to the magnetic interconnection according to FIG. 3b on the left side so that the pole orientation 6a of the center interconnection magnet 2a is disposed in this transversal plane 10′, while the pole orientations 6b, 6c of the interconnection magnets 2b, 2c connected on the lateral outside have pole orientations 6b, 6c in the longitudinal direction 10, wherein the pole orientations, however, are oriented against one another, namely towards the center interconnection magnet 2a.

According to FIG. 4 this yields a magnetic field which is significantly amplified in the use-direction 7 in which also the pole orientation 6a of the center interconnection magnet 2a is also disposed in this arrangement, and on this side the scatter fields are configured as a strong double torus while the scatter field is only extremely weak on the side of the longitudinal direction 10 of the interconnection magnet 4 that is oriented away from the use-direction.

Thus a magnetic interconnection 4 of this type is particularly well suitable for an encoder magnet 3 for a position sensor 11 whose sensor element is typically straight and elongated and in which the magnetic interconnection 4 is arranged so that its use-direction 7 extends in a radial direction and transversal to the extension of the position sensor 11.

FIG. 5 also illustrates a magnetic interconnection 4 including three interconnection magnets 2a-c in which the pole orientation 6a of the center interconnection magnet 2a, however, is disposed in longitudinal direction 10 of the magnet interconnection.

The pole orientations 6b, 6c of the two interconnection magnets 2b, 2c connected laterally thereto are oriented transversal to the longitudinal direction 10 and thus parallel to the transversal plane 10′ of the magnet interconnection 4, which in turn yields an arrangement that is symmetrical to the center plane 10′, however the pole orientations 6b, 6c of the two outer interconnection magnets 2b, 2c are oriented opposite to one another.

This yields a magnetic field in which a strong partial torus that is arranged on the transversal plane 10′ is configured as a magnetic field on one side of the longitudinal direction 10, while only a very weak residual torus that is closely adjacent to the magnet interconnection remains on the opposite side. On the face sides of the magnetic interconnection 4 a respective scatter field is configured as a partial torus, wherein the faces are symmetrical to one another about the transversal plane 10′.

This yields a strong magnetic field in a use direction 7, wherein the use direction is parallel with but opposite to the pole orientation of the center interconnection element 2a and wherein the strong magnetic field is arranged remote from the magnetic interconnection 4 on one side of the longitudinal direction 10 and is in particular configured for arranging an angle sensor 12 in this portion whose measurement axis 12′ about which the angular position of the magnetic field shall be measure by the angle sensor 12 intersects the pole plane of the magnetic interconnection remote from the longitudinal direction 10 of the magnetic interconnection 4, wherein the measurement axis intersects the pole plane in particular in a perpendicular manner, wherein the pole plane is defined by the pole orientations 6a-c of the interconnection magnets 2a-c of the magnet interconnection 4.

The magnet interconnections 4 of FIGS. 4 and 5 thus in spite of their different configurations have in common that the pole orientation changes continuously along the longitudinal direction 10 in the magnetic interconnection from one joining interconnection magnet to another respectively in the same direction of rotation, e.g. starting at the right interconnect magnet 2b to the left interconnect magnet 2c respectively by 90° counterclockwise. The FIGS. 6a and b illustrate variations of the embodiments according to FIGS. 4 and 5.

FIG. 6a illustrates a variation of the solution according to FIG. 5 in which the center magnet 2a is replaced by an interconnection element preferably made from magnetizable material alternatively also made from non-magnetizable material. As apparent the use field is symmetrically configured about the longitudinal direction 10, thus no side of the longitudinal direction is preferred or amplified.

FIG. 6b illustrates a variation of the embodiment of FIG. 4 in which the center interconnect magnet 2a is replaced with an interconnect element 4a made from magnetizable material or alternatively non-magnetizable material which yields a double torus as a magnetic field, wherein the double torus is configured with identical strength about the longitudinal direction 10 in all directions. FIG. 7 illustrate basic variants for arranging the interconnect magnets 2a-c and their pole orientations 6a-c in analogy to the embodiment of FIG. 4, thus respectively with the pole orientation 6a of the center interconnect magnets 5a in a direction of the transversal plane 10′ of the magnet interconnection 4. FIG. 7b thus corresponds to the arrangement of the pole orientations according to FIG. 4, thus also FIG. 7c, while the pole orientations of the outer magnets for FIG. 7a are not oriented towards one another but away from one another which, however, only has a relatively small influence upon the magnetic use field and in particular does not influence its orientation. FIGS. 7b and 7c furthermore illustrate that in addition to the pole orientations also the dimensions of the particular interconnect magnets 5a, b, c can be varied as a function of their orientation and the desired direction of the use field. The magnetic field, however, is developed the stronger in use direction, the more elongated the center interconnect magnet 5a is in the direction of its pole axis 6a which is implemented in FIG. 7. On the other hand side the scatter field is minimized, the wider the interconnect magnets 5b, c are configured in a direction transversal to their pole axes 6b, c, wherein the interconnect magnets 5b, c laterally connect to the center interconnect magnet 5a as illustrated e.g. in the subsequent realistic field line depictions for the embodiment according to FIG. 8.

FIG. 7c illustrates a solution with different dimensions for the two lateral interconnect magnets 5b, c which can be required in particular applications for non-symmetrical configurations of the magnetic field.

FIG. 7d illustrates an important additional variant in which the pole orientations 6b, c for the basic solution according to FIG. 4 are not precisely aligned with the longitudinal direction 10 of the magnetic interconnection 4 but are arranged at a slant angle thereto, however stewed into the direction in which also the pole orientation 6a of the center interconnect magnet 5a is oriented. Thus, another amplification of the magnetic field can be caused in use-direction 7.

Thus, a comparison of the field lines of FIG. 8 with the field lines of FIG. 4 shows that the scatter fields change their shapes to a small extent but they do not become stronger, but rather weaker and the scatter field is even slightly spatially expanded on the side exactly opposite to the use-direction.

However, the magnetic field is configured with the same strength in use-direction 7.

Simultaneously, however, the extension of the magnetic interconnection is much smaller in the solution according to FIG. 8, namely cube shaped compared to the extension in FIG. 4 which has the advantage that a magnetic interconnection according to FIG. 8 can be housed without any problem in the provided small installation space for the encoder magnets 4 e.g. for position sensors 11 without any problem, which is not always possible for the elongated interconnect magnet according to FIG. 4.

FIG. 9a only illustrates the center interconnection element 4a of an interconnect magnet 5a, while the two interconnection elements 4b, c connected on the outside are made from magnetizable material but are not permanent magnets themselves.

Accordingly a magnetic field is generated that is rotation symmetrical to the longitudinal direction 10.

FIG. 9b however corresponds to the solution according to FIG. 8 with three interconnect magnets 5a-c that are sized accordingly and arranged in the center of the magnet interconnection wherein an additional interconnect element 4d, e configured e.g. as a magnetizable flux conductor element is additionally arranged at the faces of the magnet interconnection.

In the solution according to FIG. 9c connected magnets 5d, e are applied instead of interconnection elements 4d, e to the magnet interconnection according to FIG. 9b to the faces from the outside, wherein the pole orientations 6d, e of the connected magnets in turn extend parallel to the transversal plane 10′ but respectively opposite to the pole orientation 6a of the center interconnect magnet 5a.

FIG. 10 in principle illustrate depictions of arrangements of pole orientations based on the arrangements of FIG. 9b, c which correspond to the basic schematic in FIG. 10a.

In FIG. 10c, however, the pole orientations which extend in the direction of the transversal plane 10′ are respectively arranged in the same direction and in FIG. 10b the pole orientations extending in the longitudinal direction 10 are respectively oriented from the center outward. The difference between the solutions of FIGS. 10c and 10d is also that the pole orientations aligned in longitudinal direction are oriented in one case towards the center and in the other case towards the outside.

The embodiments of FIG. 11 are respectively supplemented over the embodiments of FIG. 10 at each face of the magnet interconnection 4 respectively by an additional interconnect magnet 5f, g, wherein the pole orientations of the interconnect magnets in longitudinal direction 10 are either respectively oriented towards the center or respectively oriented towards the outside.

FIG. 12 illustrates a field line pattern similar to the embodiment of FIG. 11a, wherein the pole orientations of the interconnect magnets 5a, d, e whose pole orientations 6a, d, e extend parallel to the transversal plane 10′ are opposite to one another with respect to the center pole plane and additionally the pole orientations of the other interconnect magnets which are respectively also aligned with the longitudinal direction 10 are selected in an alternating manner opposite to one another.

FIG. 13 illustrates another embodiment that is improved over the embodiment of FIG. 12 and which includes additional interconnection elements made from magnetizable material additionally arranged at the faces.

### REFERENCE NUMERALS AND DESIGNATIONS

1 Sensor
2, 2′, 2″ Permanent magnet
3 Encoder magnet
4 Magnetic interconnection
4a, b . . . Interconnection elements
5a, b Interconnection magnets
6″,6′, 6a, b Pole orientations
7 Use direction
8″, 8′, 8 Field line
9 Contact surface
10 Longitudinal direction
10′ Transversal plane
11 Position sensor
12 Angle sensor
12′ Measurement axis

1. A magnetic field sensitive sensor (1) comprising a permanent magnet (2) configured as a position giving element,
wherein the permanent magnet (2) is a magnetic interconnection (4) including plural interconnection elements (4a, b . . . ) that are magnetizable or non-magnetizable, including plural interconnection magnets (5a, b . . . ),
wherein the interconnection magnets (5a, b) with diverging pole orientations (6a, b) are arranged proximal to one another, so that their magnetic fields interfere with one another.

2. The magnetic field sensitive sensor (1) according to claim 1, wherein the interconnection magnets (5a, b) are arranged so that a field strength of the magnet interconnection (4) in the intended use direction (7) is substantially increased and simultaneously the field strength in other directions, in particular all other directions, thus the scatter directions is reduced.

3. The magnetic field sensitive sensor (1) according to claim 1 including a permanent magnet (2) with three interconnection magnets (5a, b),
wherein the center element in pole orientation (6) is as long as possible relative to the length transversal to the pole orientation, at least twice as long, better at least three times as long, better at least four times as long, and
wherein the joining outer interconnection magnets (5a, b) transversal to their pole orientations are as long as possible relative to their dimensions in their pole orientations, in particular at least twice as wide, better three times as wide, better four times as wide.

4. The magnetic field sensitive sensor (1) according to claim 1 wherein
the magnet interconnection (4) includes an uneven number of interconnection elements (4a, b . . . ), in particular three interconnection elements (4a, b . . . ), and/or
the interconnection elements (4a, b . . . ) are arranged in a straight line row whose extension defines the longitudinal direction (10) and wherein the interconnection elements contact one another in particular, and/or
the interconnection elements (4a, b . . . ) are connected with one another in a form locking manner or are supported in particular in a non-magnetizable housing (8) and/or encased subsequently.

5. The magnetic field sensitive sensor (1) according to claim 4 wherein
the interconnect magnets (4b, c) analogously connected to the center interconnection element (4a) on both sides in outward direction have pole orientations (6b, c) that are oriented in the longitudinal direction 10 but opposite to one another, and/or
the center interconnection element (4a) is an interconnection magnet (5a) with a pole orientation (6a) transversal to the longitudinal direction (10) thus in the direction of the transversal plane (10′).

6. The magnetic field sensitive sensor (1) according to claim 1 wherein
with reference to the center interconnection element (4a) the interconnection elements (4b, c) connecting on both sides analogously in outward direction are interconnection magnets with pole orientations parallel to the transversal plane (10′) of the magnet interconnection (4), however, with opposite pole orientations (6b, c) and/or
the center interconnection element (4a) is an interconnection magnet (5a) with a pole orientation in longitudinal direction (10) of the magnet interconnection (4).

7. The magnetic field sensitive sensor (1) according to claim 1 wherein
the pole orientation respectively changes in the same direction, in particular respectively by 90 degrees from one interconnection element to another in the longitudinal direction (10) of the magnet interconnection (4) in a top view of the pole plane in which the pole orientations are disposed, and/or
magnets or magnetizable interconnection elements are arranged at respective locations on both sides of the transversal plane of the magnet interconnection extending through the center of the center interconnection element (4a).

8. A magnetic field sensitive sensor (1) according to claim 1 wherein
the sensor is a distance sensor and includes a magnetic interconnection in which the pole orientation (6) corresponds to the pole orientation of the interconnection magnets (5a, b) arranged most proximal to the center interconnection element (4a) are oriented transversal to the transversal plane of the magnet interconnection (4a, b . . . ) and in particular the longitudinal direction of the magnet interconnection (4a, b . . . ) extends parallel to the measurement direction of the sensor and/or
the magnets arranged most proximal to the center interconnection element (4a) are inclined relative to the transversal plane with their pole orientations (6 . . . ) and are oriented in a direction towards the sensor element.

9. The magnetic field sensitive sensor (1) according to claim 1 wherein
the sensor (1) is an angle sensor (12) and includes a magnetic interconnection (4a, b . . . ) in which the pole orientations of the interconnection magnets (5a, b) arranged most proximal to the center interconnection element (4a) are oriented parallel to the transversal plane (10) of the magnet interconnection (4a, b) and/or
the magnet interconnection includes flux conductor elements made from magnetizable material on the side oriented away from the use direction, in particular in all scatter directions.

10. The magnet interconnection including plural particular magnets comprising:
the magnet interconnection includes plural, in particular magnetizable interconnection elements (4a, b . . . ) among them plural interconnection magnets (5a, b)
wherein the interconnection magnets (5a, b) viewed in longitudinal direction are arranged with pole orientations (6 . . . ) deviating from one another.

11. The magnet interconnection including plural particular magnets according to claim 10, wherein
the pole orientations (6 . . . ) deviating from one another are arranged relative to one another so that the field strength in the desired use direction is substantially increased and simultaneously its remote effect in the scatter directions, thus in particular all directions is reduced and/or
in a position sensor (11) the longitudinal direction (10) of the magnet interconnection (4) is oriented parallel to the longitudinal extension of the sensor element, in particular the wave conductor and in particular the pole orientation (6, . . . ) of the center interconnection magnet (5b) is arranged transversal to the orientation of the sensor element and in particular oriented toward the sensor element.

12. The magnet interconnection including plural particular magnets according to claim 11, wherein
the sensor (1) is a rotation angle sensor and the interconnection element (4a, b) is arranged with its longitudinal direction parallel to a tangential direction about the rotation axis of the angle sensor, and
in particular the pole orientation (6 . . . ) of the center magnet is arranged in longitudinal direction (10) of the interconnection magnet (5a, b).
